(19) United States
(12) Patent Application Publication
(10) Pub. No.: US 2023/0040268 A1
(43) Pub. Date: Feb. 9, 2023

(54) SPLIT WAVEGUIDE FILTER

(71) Applicant: K-Form, Inc., Sterling, VA (US)

(72) Inventor: Callye KEEN, Sterling, VA (US)

(21) Appl. No.: 17/788,072

(22) PCT Filed: Dec. 10, 2020
(86) PCT No.: PCT/US2020/064151

§ 371 Date: Jun. 22, 2022

Related U.S. Application Data
(60) Provisional application No. 62/954,132, filed on Dec. 27, 2019.

(51) Int. Cl. G02B 6/44; G02B 6/42; H01F 17/06

(52) U.S. Cl. CPC G02B 6/4471; G02B 6/4277; G02B 6/4292; H01F 17/06; H01F 2017/065

(57) ABSTRACT

A split waveguide filter is described. The split waveguide filter includes a first waveguide section having a first outer surface and a first inner surface and a second waveguide section having a second outer surface and a second inner surface. When the first waveguide section and the second waveguide section are mated together, the first inner surface and the second inner surface form a waveguide aperture. The split waveguide filter also includes a first collar clamp for securing a first portion of the mated first waveguide section and second waveguide section together; and a second collar clamp for securing a second portion of the mated first waveguide section and second waveguide section together.

### TECHNICAL FIELD

The present invention generally relates to waveguide filters/shields for minimizing electromagnetic interference (EMI) entering or leaving an enclosure.

### BACKGROUND

EMI can enter (or leave) enclosures, such as computer systems, in various ways. For examples holes or other openings may be provided in the walls of the enclosures of such computer systems to enable cables ingress to, or egress from, the enclosures. Fiber optic cables have become a medium of choice for carrying data into and out of such enclosures. While the fiber optic cables themselves do not radiate EMI, since they are made of glass fibers, the openings in the enclosure which enable the fiber optic cables to pass into and out of the enclosures can do so.

One way to avoid this problem is to shield the openings with a waveguide filter, an example of which can be seen in U.S. Pat. No. 6,434,312 (the '312 patent), FIG. 1 of (which is reproduced as FIG. 1 herein). Therein, an enclosure 10 which, may house a computer system for example, has an opening 12 through which a waveguide filter 14 extends. The waveguide filter 14 has a circular aperture through which a fiber optic cable 16 is fed into the enclosure 10. The fiber optic cable 16 has a connector 18.

As described in the '312 patent, the waveguide filter 14 uses the general electromagnetic principle of waveguides that waveguides allow electromagnetic waves to propagate therethrough as long as the frequency of the electromagnetic wave is higher than the cutoff frequency of the waveguide. The cutoff frequency of the waveguide is determined by the geometry of the waveguide and various factors associated with the media (e.g., air, etc.) within the waveguide as described below.

Thus, by designing a waveguide filter with a geometry which is tuned to a particular cutoff frequency below which EMI energy should not be allowed to propagate, an enclosure can be safeguarded against anticipated EMI propagation even when openings are provided in the enclosure for, e.g., fiber optic cables. The '312 patent describes several equations which can be used to determine an optimal diameter of a waveguide filter's aperture based on the desired cutoff frequency. For example, according to the '312 patent, the cutoff frequency for a waveguide having a circular cross-section can be expressed as:

$${f}_{cutoff} = \frac{1.841 \vert}{2 π a \sqrt{ϵμ}} , where$$

f_{cutoff} is the cutoff frequency of the waveguide in Hertz;
a is the diameter of the circular aperture of the waveguide in meters;
ϵ is the permittivity of the media (e.g., air) within the waveguide; and
μ is the permeability of the media within the waveguide.
As can be seen from the foregoing equation, the cutoff frequency of the waveguide is inversely proportional to the diameter of the aperture in the waveguide. This means that as the desired cutoff frequency increases, the desired size of the aperture gets smaller.

This aperture sizing aspect of waveguide filters leads to another challenge: connectors and larger bundles of fiber optic cables may not be able to fit through smaller apertures in waveguide filters making it difficult or impossible to directly feed the desired fiber optic cable(s) through the waveguide filter. In some cases, since the connectors don't fit through the aperture, installers of such waveguide filters have had to feed fiber optic cable without connectors through the waveguide and into the enclosure, and then assemble the connectors inside the enclosure—a complicated manufacturing task.

Some solutions to this problem have been explored. For example, as described in U.S. Pat. No. 4,849,723 and U.S. Patent Publication No. 2017/0090120, and as shown in FIG. 2 (which is a version of FIG. 2 of the '723 patent), a waveguide filter 100 is formed by a housing 110 through which a plurality of longitudinally extended bores 130 and 140 are formed. One of the bores 140 is centrally located within housing 110 and overlaps each of the remaining plurality of bores 130 which form waveguide passages. Waveguide passages 130 are located radially at outer portions of the central passage 140. Each of the individual waveguide passages 130 and central passage 140 have a common longitudinal access opening extending the length of housing 110. Central passage 140 has a diameter considerably larger than the diameter of waveguide passage 130. A closure for central passage 140 and each of the longitudinal access openings between central passage 140 and the waveguide passages 130 is provided by a plug 120 insertable within central passage 140. Plug 120 is releasably coupled to housing 110, forming a closure for the longitudinal access opening of each waveguide passage 130, and thereby forming one wall of each waveguide 130.

Since plug 120 forms a portion of the outer wall for each of waveguide passages 130, forming a closure for the longitudinal waveguide access opening, a tight close tolerance fit is required to achieve high frequency attenuation for the waveguide filter feed-through 100. Thus, a means for fastening plug 120 within housing 110 is provided to ensure a substantially contiguous contact between tapered portion 122 of plug 120 and the tapered central passage 140 of housing 110.

However the solution described in the '723 patent and the '120 patent publication is still limited in terms of the size of connector and/or optical cable which will fit through central bore. Accordingly, there is a need for another waveguide filter solution that will enable connectors and cables of any size to be easily shielded without reducing the desired EMI attenuation.

### SUMMARY

In one embodiment, a split waveguide filter includes a first waveguide section having a first outer surface and a first inner surface and a second waveguide section having a second outer surface and a second inner surface. When the first waveguide section and the second waveguide section are mated together, the first inner surface and the second inner surface form a waveguide aperture. The split waveguide filter also includes a first collar clamp for securing a first portion of the mated first waveguide section and second waveguide section together; and a second collar clamp for securing a second portion of the mated first waveguide section and second waveguide section together.

According to another embodiment, a split waveguide filter kit includes a first waveguide section having a first outer surface and a first inner surface, a second waveguide section having a second outer surface and a second inner surface which can be mated with said first waveguide section to form a waveguide aperture, a first collar clamp and a second collar clamp.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 depicts an enclosure having a waveguide filter which shields a fiber optic cable passing through the enclosure;

FIG. 2 depicts a conventional waveguide filter adapted with a plug to allow fiber optic connectors to be passed through the waveguide filter;

FIG. 3A shows a split waveguide with the two waveguide sections separated around a fiber optic cable according to an embodiment;

FIG. 3B shows a split waveguide with the two waveguide sections mated around a fiber optic cable according to an embodiment;

FIG. 4 illustrates an isometric exploded view of a connecting mechanism for a split waveguide according to an embodiment;

FIG. 5 illustrates an isometric exploded view of a connecting mechanism for a split waveguide with a second connecting mechanism on another end according to an embodiment;

FIG. 6 depicts a fully assembled split waveguide according to an embodiment;

FIG. 7 shows an end view of the split waveguide of FIG. 6; and

FIG. 8 shows a side view of the split waveguide of FIG. 6.

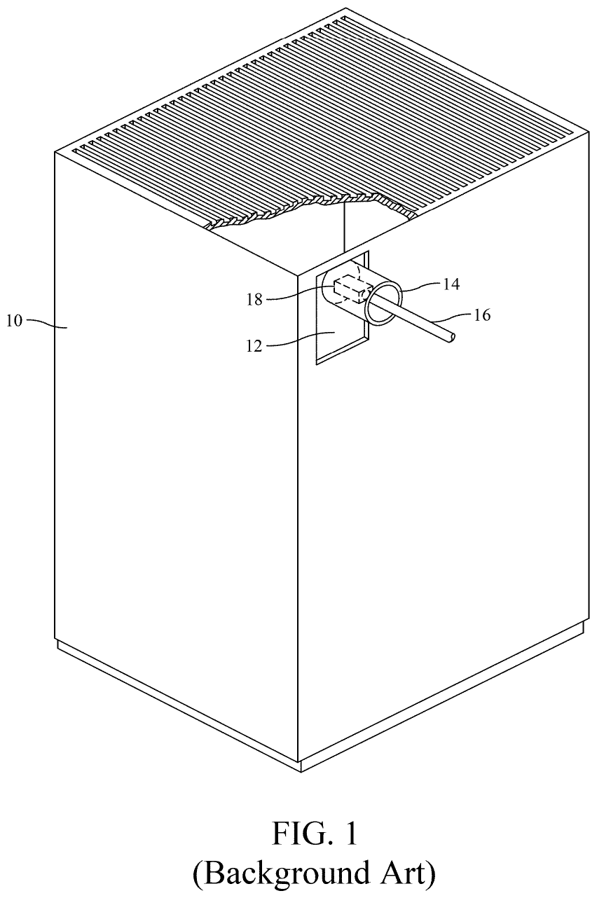

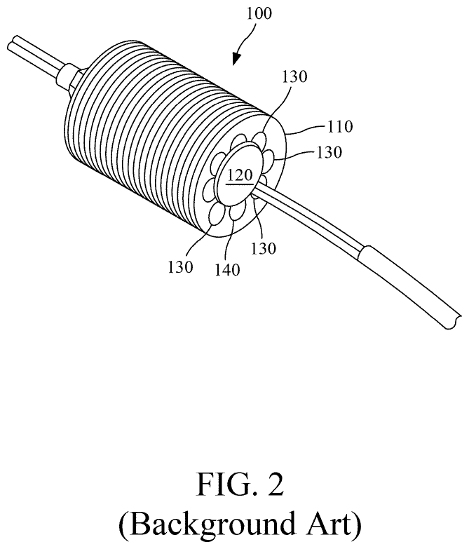

### DETAILED DESCRIPTION

In the following description, for purposes of explanation and non-limitation, specific details are set forth, such as particular dimensions, elements entities, techniques, protocols, etc. in order to provide an understanding of the described technology. It will be apparent to one skilled in the art that other embodiments may be practiced apart from the specific details disclosed below. In other instances, detailed descriptions of well-known methods, devices, techniques, etc. are omitted so as not to obscure the description with unnecessary detail. Individual function blocks are shown in the figures.

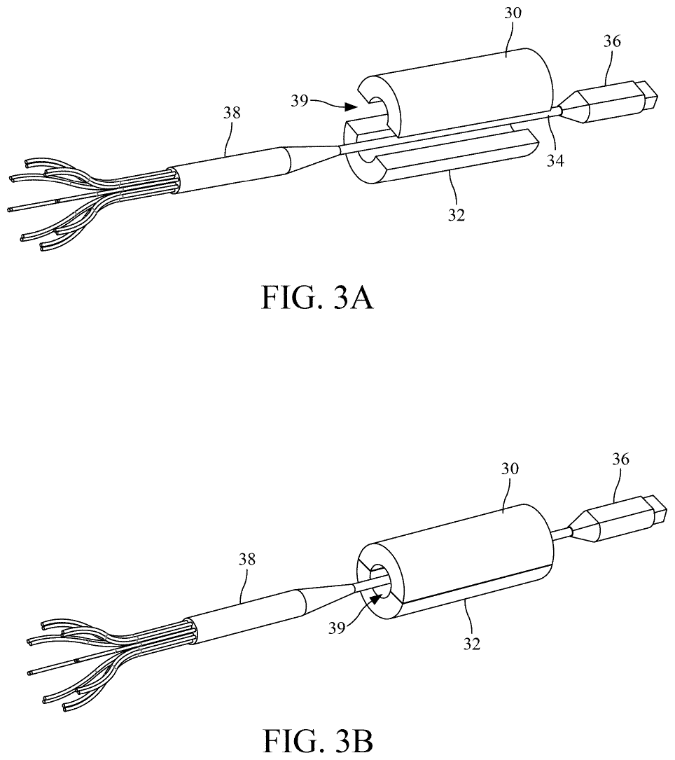

As described in the Background section, there are problems associated with existing waveguide filters, e.g., providing a waveguide filter that has a suitably small aperture diameter while also easily accommodating fiber optic bundles having connectors which exceed that diameter. According to embodiments described herein the waveguide filter is split into two (or more) parts such that the waveguide filter can be put together around a section of the fiber optic cable which has a diameter which is less than the aperture diameter and, therefore, there is no need to try to feed (or later install) the larger connectors through the aperture. An example can be seen in FIG. 3A, wherein the waveguide filter has two sections 30 and 32 which can be placed around a thinner portion 34 of the fiber optic cable without, e.g., needing to try to feed the larger connectors 36 and 38 through the aperture 39. FIG. 3B shows the embodiment of FIG. 3A with the two waveguide sections 30 and 32 pushed together around the fiber optic cable.

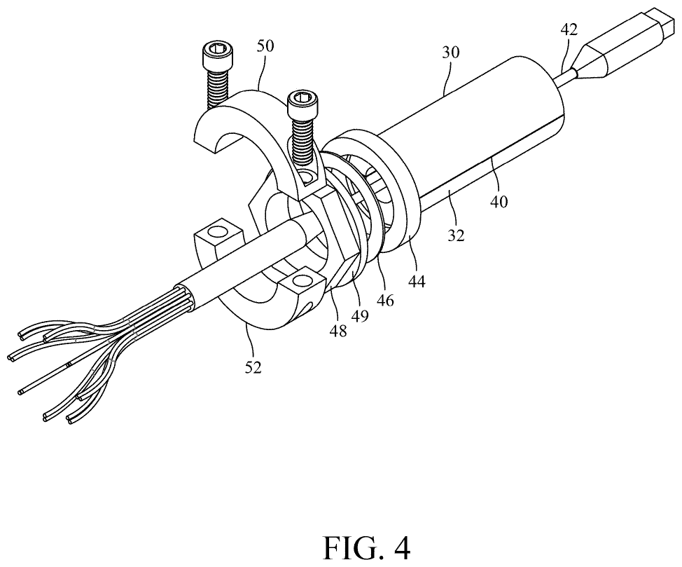

In order to obtain the desired EMI attenuation which the split waveguide of FIG. 3B can provide, Applicant has determined that it is important for the two waveguide sections 30 and 32 to be tightly coupled together to thereby minimize the size of the space or gap 40 (see, e.g., FIG. 4) between the two sections 30 and 32 when they are placed around a fiber optic cable 42 in order to maximize the shielding characteristics of the split waveguide. FIG. 4 shows one coupling mechanism in an exploded, isometric view. In practice, and as shown in later figures, two such coupling mechanisms will be used to secure the waveguide sections 30 and 32 together, i.e., one coupling mechanism on each side of the enclosure plate.

Therein, a conductive (e.g., monel) gasket 44 is placed over the two waveguide sections 30 and 32 and is slid up against the enclosure plate (not shown in FIG. 4) to ensure good conductivity between the waveguide and the enclosure plate. In one embodiment, the monel gasket 44 can be fabricated as a conductive mesh which compresses much like a fabric. The conductive gasket is followed by a washer 46 and then a threaded flanged nut 48, 49. Although not shown in FIG. 4, the outside surface of both waveguide sections 30 and 32 can be threaded such that the threaded flanged nut 48 can be rotated onto the two waveguide sections 30 and 32, pressing the washer 46 and the gasket 44 tightly up against one side of the enclosure plate. The threaded flanged nut 48, 49 and washer 46 provide even compression of the gasket 44 and also prevent the gasket 44 from becoming caught in the threads of the nut 48. The threaded flanged nut 48, 49 is followed by a two-section collar clamp 50, 52 which provides easy to install clamping pressure to the two waveguide sections 30 and 32 to minimize the gap 40 therebetween.

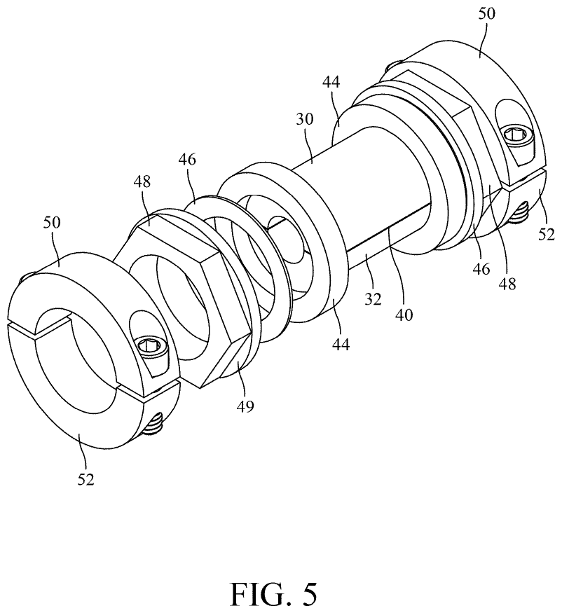

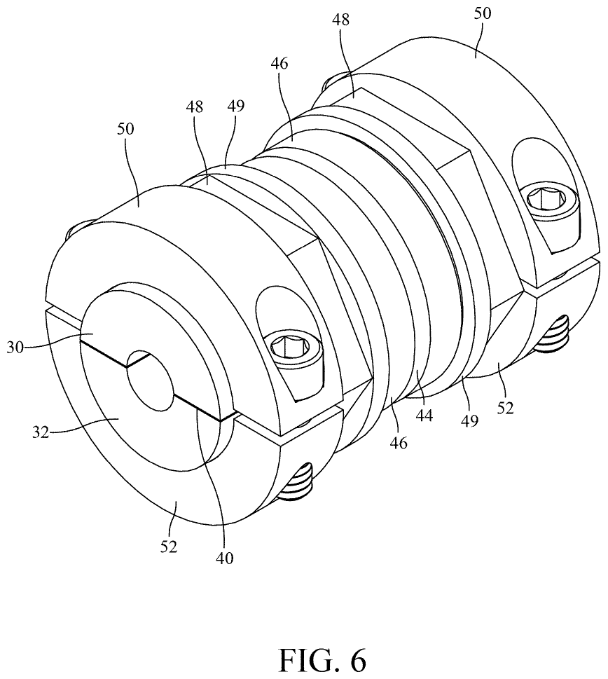

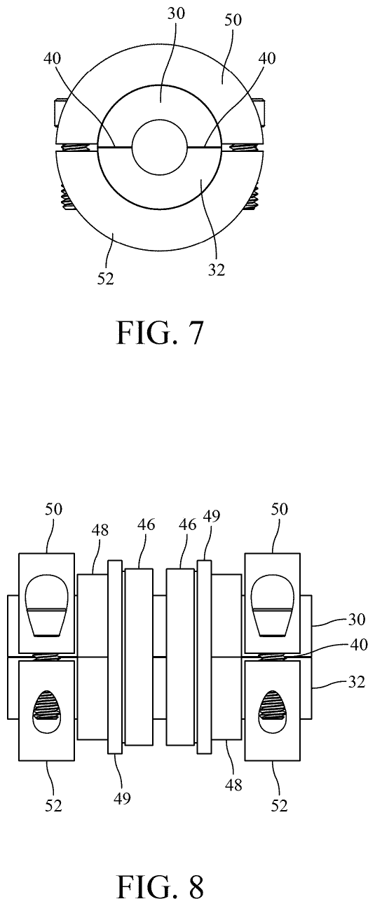

As mentioned above, FIG. 4 illustrates one coupling mechanism 44-52 in an exploded view. FIG. 5 shows an embodiment wherein two coupling mechanisms 44-52 are used to tightly couple the waveguide sections 30 and 32. FIG. 6 shows an isometric view of the embodiment of FIG. 5 with both coupling mechanisms completely installed on the waveguide sections 30 and 32. FIGS. 7 and 8 depict an end view and a side view of the split waveguide embodiment of FIG. 6, respectively.

Although the embodiments described herein depict a circular waveguide, those skilled in the art will appreciate that the waveguide and/or waveguide aperture can have other cross-sectional shapes, e.g., square or rectangular. Moreover, while the embodiments described herein depict the waveguide as being used to shield fiber optic cable, the waveguide filters described herein can be used to shield other types of elements.

When an element is referred to as being “connected”, “coupled”, “responsive”, or variants thereof to another element, it can be directly connected, coupled, or responsive to the other element or intervening elements may be present. In contrast, when an element is referred to as being “directly connected”, “directly coupled”, “directly responsive”, or variants thereof to another element, there are no intervening elements present. Like numbers refer to like elements throughout. As used herein, the singular forms “a”, “an” and “the” are intended to include the plural forms as well, unless the context clearly indicates otherwise. Well-known functions or constructions may not be described in detail for brevity and/or clarity. The term “and/or” includes any and all combinations of one or more of the associated listed items.

As used herein, the terms “comprise”, “comprising”, “comprises”, “include”, “including”, “includes”, “have”, “has”, “having”, or variants thereof are open-ended, and include one or more stated features, integers, elements, steps, components or functions but does not preclude the presence or addition of one or more other features, integers, elements, steps, components, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of various exemplary combinations and subcombinations of embodiments and of the manner and process of making and using them, and shall support claims to any such combination or subcombination.

Many variations and modifications can be made to the embodiments without substantially departing from the principles of the present solution. All such variations and modifications are intended to be included herein within the scope of the present solution.

1. A split waveguide filter comprising:
a first waveguide section having a first outer surface and a first inner surface;
a second waveguide section having a second outer surface and a second inner surface;
wherein when said first waveguide section and said second waveguide section are mated together, the first inner surface and the second inner surface form a waveguide aperture;
a first collar clamp for securing a first portion of the mated first waveguide section and second waveguide section together; and
a second collar clamp for securing a second portion of the mated first waveguide section and second waveguide section together.

2. The split waveguide filter of claim 1, wherein the first waveguide section and the second waveguide section are threaded on the first outer surface and the second outer surface, and further comprising:
a first threaded flanged nut threaded onto the mated first waveguide section and second waveguide section next to the first collar clamp; and
a second threaded flanged nut threaded onto the mated first waveguide section and second waveguide section next to the second collar clamp.

3. The split waveguide filter of claim 2, further comprising:
a first washer on the mated first waveguide section and second waveguide section next to the first threaded flanged nut; and
a second washer on the mated first waveguide section and second waveguide section next to the second flanged nut.

4. The split waveguide filter of claim 3, further comprising:
a first conductive gasket on the mated first waveguide section and second waveguide section next to the first washer; and
a second conductive gasket on the mated first waveguide section and second waveguide section next to the second washer.

5. The split waveguide filter of claim 4, wherein the first conductive gasket and the second conductive gasket are formed of a mesh made of monel.

6. The split waveguide filter of claim 1, wherein the waveguide aperture is dimensioned to attenuate electromagnetic interference below a predetermined cutoff frequency.

7. A split waveguide filter kit comprising:
a first waveguide section having a first outer surface and a first inner surface;
a second waveguide section having a second outer surface and a second inner surface which can be mated with said first waveguide section to form a waveguide aperture;
a first collar clamp; and
a second collar clamp.

8. The split waveguide filter kit of claim 6, wherein the first waveguide section and the second waveguide section are threaded on the first outer surface and the second outer surface, and further comprising:
a first threaded flanged nut; and
a second threaded flanged nut.

9. The split waveguide filter kit of claim 8, further comprising:
a first washer; and
a second washer.

10. The split waveguide filter kit of claim 9, further comprising:
a first conductive gasket; and
a second conductive gasket.

11. The split waveguide filter kit of claim 10, wherein the first conductive gasket and the second conductive gasket are formed of a mesh made of monel.

12. The split waveguide filter kit of claim 7, wherein the waveguide aperture is dimensioned to attenuate electromagnetic interference below a predetermined cutoff frequency.
